(19) United States
(12) Patent Application Publication
(10) Pub. No.: US 2010/0108376 A1
(43) Pub. Date: May 6, 2010

(54) CONNECTION BOX FOR SOLAR PANEL

(76) Inventors: Michael Richter, Schalksmuehle (DE); Stefan Joergens, Schalksmuehle (DE)

Correspondence Address: K.F. ROSS P.C., 5683 RIVERDALE AVENUE, SUITE 203 BOX 900, BRONX, NY, 10471-0900, US

(21) Appl. No.: 12/434,708

(22) Filed: May 4, 2009

(30) Foreign Application Priority Data
May 3, 2008 (DE) 102008022056.6

(51) Int. Cl. H05K 7/20; H05K 5/00

(52) U.S. Cl. 174/548; 174/520

(57) ABSTRACT

A box for connecting an output conductor from a solar panel to a feed cable. The box has a cover, a base securable to a solar panel, closable by the cover, and formed with a first opening for the output conductor and at least one second opening for a feed cable, and means in the base for securing the conductor directly in electrical conduct to the cable.

### FIELD OF THE INVENTION

The present invention relates to a connection box. More particularly this invention concerns a connection box for a solar panel.

### BACKGROUND OF THE INVENTION

A typical connection box, in particular for solar panels, comprises a cover that upwardly closes a base that is itself attached to the back of a solar panel. The base has a first opening for at least one output conductor or cable from the panel and at least one opening for a feed cable exiting from the panel and going to the network using the solar-generated electricity. The base also has a compartment that holds circuit elements for connecting the panel-output cable to the feed cable.

A connection box of this type is disclosed, for example, in 10 2005 008 123 A1. The base of the connection box here has a strip-conductor structure that is provided with cable clamps. The cable clamps function to connect the feed cables and the panel-output cables to the strip-conductor structure.

In US 2005/0230140 screw-type terminals are provided to which the panel-output cables and feed cables are electrically connected by strip-conductor structures.

U.S. Pat. No. 7,444,743 discloses a strip-conductor structure inside a connection box in which the feed cables and panel-output cables are connected by crimping to the strip-conductor structure. For bridge diodes, the strip-conductor structure forms forked-spring-contact-type contact clips.

DE 20 2005 018 884 describes a connection box whose opposite side walls has holes through which panel-associated panel-output cables and feed cables are routed into the connection box. Bridge-like clamping components are placed between the cables to be connected and are analogous to the strip-conductor structures. At their ends, these clamping components have clamp springs to make the contact of the cables and provided with contact openings in which the bridge diodes can be inserted.

In the case of all of the above-referenced publications, the installation cost of producing the electrical connection of the panel-associated panel-output cable and feed cable is significant. The connection-clamping terminals presented in numerous variants must in each case be spread by a tool, then the appropriate leads must be inserted, after which the tool must then be removed. In some cases, the terminal clamps must also be closed by the tool. The same is true for the installation of bridge diodes. In addition, fitting the bases of the connection boxes with the appropriate circuit elements also involves a significant cost. The connection box itself must be formed with various retaining elements for attachment of the strip conductors, and the strip conductors must be stamped, shaped, inserted into the connection box, and attached there.

### OBJECTS OF THE INVENTION

It is therefore an object of the present invention to provide an improved connection box for solar panel.

Another object is the provision of such an improved connection box for solar panel that overcomes the above-given disadvantages, in particular that simplifies the electrical connection of panel-output and feed cables.

### SUMMARY OF THE INVENTION

A box for connecting an output conductor from a solar panel to a feed cable. The box has according to the invention a cover, a base securable to a solar panel, closable by the cover, and formed with a first opening for the output conductor and at least one second opening for a feed cable, and means in the base for securing the conductor directly in electrical conduct to the cable.

The direct electrical contact between of the panel-output cable and the feed cable eliminates the need for the disadvantageous strip-conductor structures and contacts of the prior art and the need to manipulated them with tools. As a result, the material cost, as well as production and installation costs are significantly reduced.

Thus the invention uses a direct electrical contact between the panel-output cable and the feed cable so long as the panel-output cable is near the region of the end of the feed cable.

A preferred embodiment of the invention is characterized in that the panel-output cable is engaged with an electrically conductive and mechanically reinforced end of the feed cable. The mechanical reinforcement of the end of the feed cable, in particular, of the stripped conductors, enables the panel-output cable and feed cable to be connected in a secure and fixed manner using appropriate means.

Provision is made whereby the end of the feed cable is stripped and mechanically reinforced by a cable end sleeve. Attaching a cable end sleeve is a simple and appropriate measure for mechanically reinforcing a lead composed of multiple conductors, that is stranded wire. A mechanical reinforcement can also be effected just as well by solder, that is tinning the stranded-wire bundle. Additionally, a massive single conductor is mechanically stiff enough to use as is within the scope of the invention.

Within the scope of the invention, what is then also involved is a direct engagement of panel-output cable on the feed cable when the leads are enveloped by a reinforcing means as long as the panel-output cable is fitted in the region of the core of the feed cable.

From the point of view of installation, the panel-associated panel-output cable can be engaged with the feed cable in a simple manner by a contact clip, in particular, if the contact clip is designed as a spring having an approximately Ω-shaped cross-section.

In an especially preferred embodiment of the invention, the contact along with the panel-output cable and the feed cable form a self-supporting connection assembly. This means that the assembly composed of the panel-output cable, feed cable, and contact clip do not require any additional support for securely establishing a permanent electrical connection between the cable and the panel conductor.

From the point of view of assembly, it is especially advantageous for the contact to be provided on the bottom face of the cover facing the base component. In this type of design of the invention, closing the box and making an electrical connection of panel-output cable and feed cable are effected in a single operation.

In another embodiment, provision is made whereby the connection box is of multipolar design, thus accepting at least two panel-output cables and two feed cables, joinable by two clips, or more. In connection boxes of this type, it often happens that a diode bridging two panel-output cables is provided. In order to connect this bridge diode to two panel-output cables, provision is made whereby the bridge diode makes contact with each contact clip that are each mounted on the cover of the connection box and support the diode.

A significant problem of the prior art is posed by the heat emitted by the various functional components placed inside the connection box. One example in particular here is the currently widely used shunt diodes that can reach temperatures of up to 180° C. However, active or passive switching components provided in the future are also emitters of heat.

This waste heat negatively affects the cables of the solar cells on a solar panel. A solution to remedy the heat problem must be provided both for crystalline-type solar panels as well as for the increasingly used thin-film panels.

One embodiment of the invention therefore proposes that the cover have a heat-conducting material on its bottom face facing the base, in particular, that is in contact through thermal bridges with the heat-emitting components inside the box.

The waste heat is passed through the proposed heat-conducting material directly away from the panel to the cover of the box. This is typically ventilated from outside, thereby allowing the heat to be effectively dissipated.

In a first embodiment, provision is made whereby the heat-sink is in contact with heat-emitting components inside the box by spring-elastic pressure elements functioning as thermal bridges, in particular, flexible tongues formed by the heat-conducting plate.

The especially preferred approach, however, is one where the contact for fitting the panel-output cable on the feed cable functions as thermal bridge.

Fabrication is significantly simplified if the contact is formed by the heat-conducting plate.

Dissipation of the heat from the diode can be done especially effectively if the body of the diode constituting the heat-emitting component is mounted directly on the heat-conducting material, in particular, the heat-conducting plate. This obviously also applies in the case of every other heat-emitting circuit element inside the connection box.

Identified as circuit elements are all those elements that affect the conduction of electrical current from the solar panel into the electrical network.

### BRIEF DESCRIPTION OF THE DRAWING

The above and other objects, features, and advantages will become more readily apparent from the following description, reference being made to the accompanying drawing in which:

FIG. is a perspective view from below of the cover of the box according to the invention;

FIG. 2 is a perspective view from above of the cover box;

FIG. 3 is a view from above of an inverted alternate cover box in accordance with the invention; and

FIG. 4 is a section taken along line IV-IV of FIG. 2.

### SPECIFIC DESCRIPTION

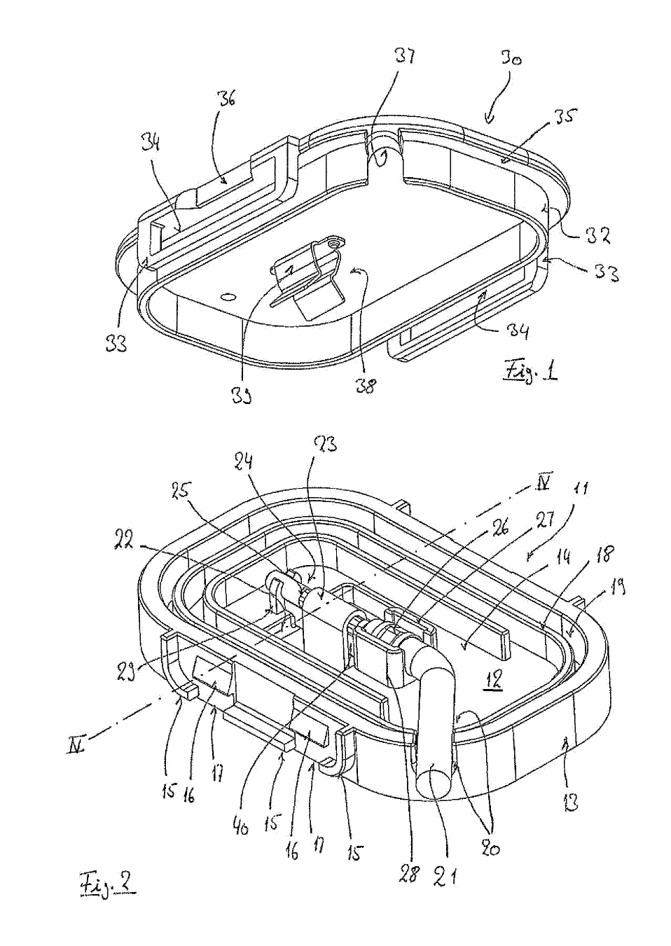

As seen in FIGS. 1 and 2 a connection box 10 according to the invention has a base 11 (FIG. 2) with a generally rectangular and planar floor 12 and an annular side wall 13 that define a compartment 14 serving to hold circuit elements. On two opposing sides at its outer surface, the side wall 13 is provided with guides 15 and projecting locking lugs 16. Below the locking lugs 16, the guides 15 have tool-guide slots 17. (The references to “up” and “down” being purely for convenience of description, since the box is often mounted inverted on the generally downwardly facing back face of a solar panel.)

An inner wall 18 parallel to the outer side wall 13 is provided inside the compartment 14 such that it is spaced relative to side wall 13 by a circumferential gap 19 from the wall 13. The side wall 13 and inner wall 18 each have aligned cable guide cutouts or holes 20 through which a feed cable 21 passes. The feed cable 21 conducts the electricity generated by the solar panel into an electricity network, optionally through additional technical equipment.

The base 12 has a hole or opening 22 through which panel-output cables 23 are routed into compartment 14 of connection box 10. These panel-output cables 23 are strip conductors whereas the feed cable 21 is a standard cable with conductors held in an outer insulating sheath.

The feed cable 21 has a stripped end 24 where its conductors are mechanically reinforced by a cable end sleeve 25. A crimp ring 26 inward therefrom in the end 24 functions as part of a strain-relief assembly. The floor 12 of the connection box 10 has two approximately U-shaped ridges 27 extending perpendicular upward from the floor 12. These ridges 27 form a holding seat 28 that is centrally grooved. This groove receives the crimp ring 26 to take up strain in the feed cable 21.

The end 24 provided with the cable end sleeve 25 of the feed cable 21 extends across the opening 22 of the floor 12 and is anchored at least on the opposite side in the compartment 28 of the opening 22. To this end, two U-forming lugs 29 on the floor 12 form a snap-in support for the cable end sleeve 25. In this case, the cable end sleeve 25 also rests on a support ridge 40 extending across the opening 22.

The panel-output cable 23 coming from the solar panel passes through the opening 22 into the connection box 10 and over the end 24 of feed cable 21 such that it is partially wrapped around the cable 11 end sleeve 25 in electrical contact therewith.

The floor 12 of the base 11 of the connection box 10 is secured by its face turned away from the cover 30 to the solar panel shown schematically at 55, in particular, by an adhesive bond 56. The opening 22 is in the region of a cutout in the solar-panel housing through which panel-output cables 23 are routed to the outside.

A cover 30 the of connection box 10 is shown in FIG. 1. It has a planar top wall 31 normally extending parallel to but space from the floor 12 and provided with an essentially circumferential collar 32 directed toward the base 11.

At opposite sides, locking lugs 33 facing the base 11 project from the cover 30 and each define a snap-in-locking opening 34. A circumferential overhanging rim 35 projecting from the cover wall 31 opposite the collar 32 is formed near the locking lugs by a tool-engagement formation 36. Similarly, the collar 32 has a cable guide cutout 37. This corresponds in terms of its position with cable guide cutouts 20 of the inner and outer side walls 13 and 18.

The bottom face of the cover wall 31 facing the base 11 is provided with a contact 38 in the form of a clip spring 39 having an approximately Ω-shaped cross-section.

When the box 10 is closed, that is, when cover 30 is mounted on the base 11, the collar 32 fits in the base-section-associated ring gap 19. To effect a gas-tight seal of connection box 10, a seal (not shown), is provided. The lug guides 15 receive the locking lugs 33 that are pushed over the wedge-shaped locking lugs 16 and grasp these from behind while locking the connection box 10 closed. The cable end sleeve 25 overlaps the clamping springs 39, which engage in the overlap region of the panel-output cable 23 and the end 24 of the feed cable 21, and are provided on the cover wall 31, when everything is closed. This ensures that panel-output cable 23 is held in a securely clamped fashion on the cable end sleeve 25.

The tool-engagement formations 17 and 36 function to allow spreading and release of the snap-in-locking connection between the locking lugs 33 and locking lugs 16, so as to allow the cover to be removed from base 11.

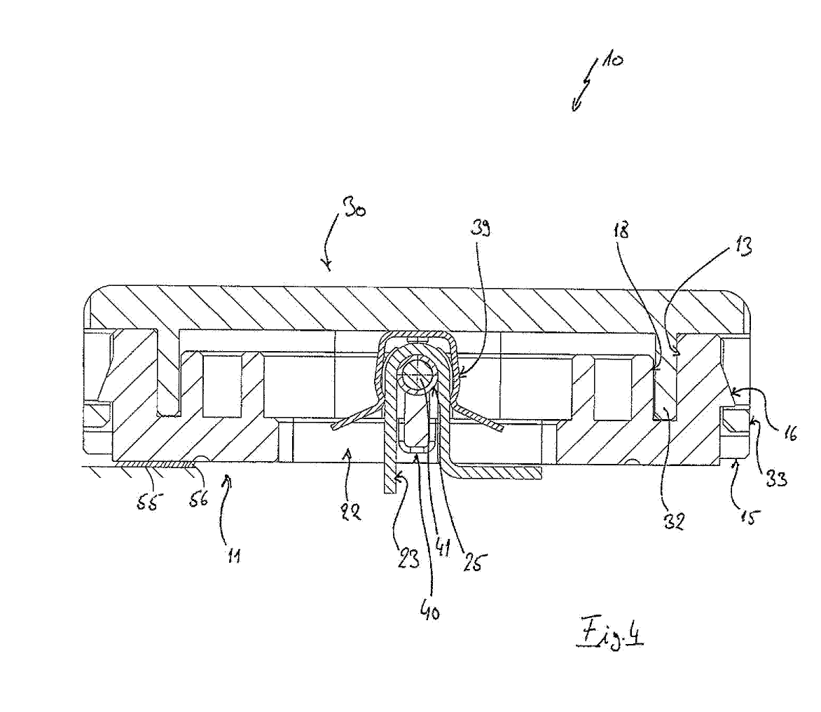

FIG. 4 shows on the right the snap-in-locking connection between the cover 30 and the base 11 by the locking lugs 33 grasping behind the locking lugs 16. Also shown is the insertion of the collar 32 in the annular gap 19 is formed between the inner side wall 18 and the outer side wall 13. The cable end sleeve 25 surrounds the core 41 composed of multiple conductors in the embodiment and mechanically reinforces this core 41. The panel-output cable 23 exiting the solar panel passes around the cable end sleeve 25. This cable end sleeve 25 itself rests on a lower support ridge 40 bridging the opening 22. The spring 39 grips the panel-output cable 23 on the cable end sleeve 25, and holds the panel-output cable 23 on the cable end sleeve 25 securely so as to form a good electrical connection.

FIG. 4 clearly shows that only the cable end sleeve 25 of the contact 39 functions as a support. The spring 39, panel-output cable 23, and cable end sleeve 28 consequently form a self-supporting connection arrangement.

It is within the scope of the invention that the clip 38 can be mounted detachably on the panel-output cable 23 and cable end sleeve 25.

In sum, a connection box 10 has been described that advantageously provides an installation-friendly, secure electrical connection between the panel-output cable 23 and the feed cable 21. The need for tool to work on conductor elements and strip-conductor structures inside the connection box has been eliminated. The simple arrangement of the panel-output cable 23 directly on an electrically conductive region of the feed cable 21 and the secure connection by a contact that only needs to be fitted in place have significant time and cost advantages for installing the connection box, in particular, if the clip 38 is mounted on the cover 30 of box 10 and the connection between panel-output cable 23 and feed cable 21 are locked together by closing the box 10.

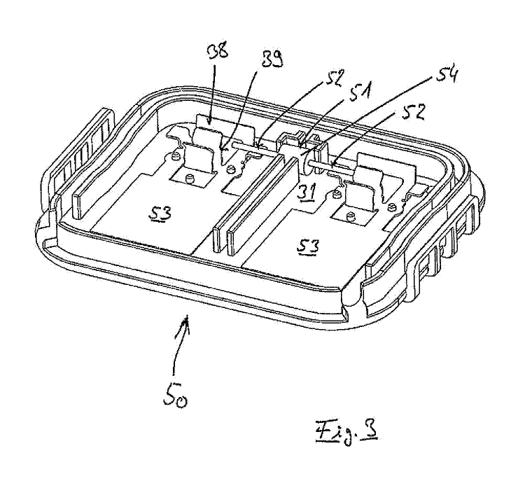

FIG. 3 shows a cover 50 of another embodiment of the invention that corresponds with another base (not shown). The connection box 10, not shown in its entirety, of this second embodiment is of multipolar design. This means that multiple panel-output cables 23 exiting the solar panel are connected to two feed cables 21 inserted into the connection box 10. In this case, this involves a two-pole connection box 10 in which, analogously to the previous description, one panel-output cable 23 is fitted on each electrically conductive and mechanically reinforced end 24 of a respective feed cable 21. Contacts 38 provided in the cover 50, which here too are designed as clamping springs 39 with an approximately Ω-shaped cross-section, ensure the good electrical connection of the panel-output cables 23 and the ends 24 of the respective feed cables 21.

In the case of multipole connection boxes 10, panel-output cables 23 are typically provided with shunt diodes 51. These prevent the solar panel from heating up, whenever solar cells are not operating in the case of parallel operation, for example, due to shading, by preventing undesired current from flowing.

Unlike the prior art referenced in the introduction, the shunt diodes are not inserted in the base using connection clamping terminals, but are instead integrated in the cover 50 and electrically connected to clamping springs 39 through their leads 52.

Since shunt diodes 51 in current applications are the main cause of waste heat, the arrangement of the shunt diode in the cover has significant advantages in thermal terms alone. The diode is thus mounted directly adjacent the usually well-ventilated end wall 31 of the cover 50 such that the waste heat can be effectively dissipated. Dissipation of the waste heat can also be significantly improved further by disposing large-area heat-sink plates, or at least one heat-conducting plate 53 on the bottom side of cover wall 31. These cooling plates—also identified as heat sinks—are connected through thermal bridges in this example leads 52, to the body 54 of the diode 51, thereby further improving heat dissipation.

In one development, not illustrated here, the diode body 54 rests directly on the cooling plate 53, diode body 54 then preferably providing as large a support area as possible.

It is also conceivable for the cover itself to be designed as the cooling body or cooling plate 53. To this end, this can be fabricated out of an efficiently-heat-conducting material, in particular, a metal such as aluminum.

If the goal is to provide additional heat-emitting circuit elements inside the base of connection box 10, these can be connected to cooling plates 53 through flexible tongues functioning as thermal bridges.

In sum, FIG. 3 shows an extremely advantageous development of the invention by which problems caused by waste heat from circuit elements supported inside the connection box 10 can be eliminated.

We claim:

1. A box for connecting an output conductor from a solar panel to a feed cable, the box comprising:
a cover;
a base securable to a solar panel, closable by the cover, and formed with a first opening for the output conductor and at least one second opening for a feed cable; and
means in the base for securing the conductor directly in electrical conduct to the cable.

2. The connection box defined in claim 1 wherein the cable has a stripped and mechanically reinforced end in contact with the conductor.

3. The connection box defined in claim 2 wherein the end is provided with a conductive reinforcement sleeve.

4. The connection box defined in claim 2 wherein the conductor is engaged around the end and the means is a clip pressing the conductor against the end.

5. The connection box defined in claim 4 wherein the clip and the feed cable are self-supporting.

6. The connection box defined in claim 4 wherein the clip is fixed on a bottom face of the cover.

7. The connection box defined in claim 6 wherein the clip is Ω-shaped.

8. The connection box defined in claim 6 wherein the box is of multipolar design and is provided with two first openings, two second openings, and two clips for two conductors and two feed cables.

9. The connection box defined in claim 8, further comprising
a circuit element mounted on the cover between the clips.

10. The connection box defined in claim 9 wherein the element is a diode.

11. The connection box defined in claim 10 wherein the diode is connected between the two feed cables.

12. The connection box defined in claim 9 wherein the element generates heat and the cover is provided with a heat sink in heat-conducting contact with the element.

13. The connection box defined in claim 12 wherein the heat sink has spring-elastic fingers forming thermal bridges bearing on the element.

14. The connection box defined in claim 9 wherein the clip is in heat-conducting contact with the element and functions as a heat sink.

15. The connection box defined in claim 14 wherein the clip is part of a heat-sink plate.
